(19) United States
(12) Patent Application Publication
(10) Pub. No.: US 2009/0302413 A1
(43) Pub. Date: Dec. 10, 2009

(54) SEMICONDUCTOR DEVICE AND STI FORMING METHOD THEREFOR

(76) Inventor: Dong-Woo Kang, Gangnam-gu (KR)

Correspondence Address: SHERR & VAUGHN, PLLC, 620 HERNDON PARKWAY, SUITE 320, HERNDON, VA, 20170, US

(21) Appl. No.: 12/476,011

(22) Filed: Jun. 1, 2009

(30) Foreign Application Priority Data
Jun. 5, 2008 (KR) 10-2008-0053175

(51) Int. Cl. H01L 29/06; H01L 21/762; C23C 14/48; C23F 1/08

(52) U.S. Cl. 257/506; 438/427; 118/620; 156/345.1; 257/E29.02; 257/E21.548

(57) ABSTRACT

A semiconductor device includes: a semiconductor substrate having a low voltage (LV) region and a high voltage (HV) region; a pad oxide film pattern and a pad nitride film pattern which are formed over the semiconductor substrate. Further, the semiconductor device includes a shallow trench isolation (STI) formed in the LV region and a STI in the HV region, with a step generated therebetween by ions with which the HV region on the semiconductor substrate is doped when an etching process is carried out using the pad oxide film pattern and pad nitride film pattern as a mask.

The present application claims priority under 35 U.S.C. 119 to Korean Patent Application No. 10-2008-0053175 (filed on Jun. 5, 2008), which is hereby incorporated by reference in its entirety.

### BACKGROUND

With increasingly high integration of semiconductor circuits, integrated circuits with different functions are incorporated in the same device. There is an increasing need for high voltage and high power transistors for multi-voltage/current driving.

A thin film transistor liquid crystal display device includes a driving circuit constituted by 5V logic and a control circuit constituted by 30 V or above (HV or high voltage) and high power transistor devices. Such HV and high power transistor devices may be realized using a dual STI (shallow trench isolation) process. In the dual STI process, topology of a STI corner and a doping profile of a semiconductor (e.g., CMOS) substrate have a great effect on such HV and high power transistor devices.

In the dual STI process, a LV region and a HV region may be separately formed in one chip to provide different STI depths by etching and patterning both regions independently using their respective masks. However, in semiconductor devices having LV and HV regions which are very close to each other, a topology formed after a first etching for the LV region may make it difficult to form a pattern for a second etching for the HV region.

### SUMMARY

Embodiments relate to a semiconductor device with a dual shallow trench isolation (STI) structure formed therein, in which a step is generated between a low voltage (LV) region and a high voltage (HV) region using an etching rate difference caused by ion doping in an etching process, and a STI forming method therefore.

Embodiments relate to a semiconductor device including: a semiconductor substrate having a low voltage region and a high voltage region, a pad oxide film pattern formed over the semiconductor substrate, a pad nitride film pattern formed over the pad oxide film; and a shallow trench isolation formed in the low voltage region and a shallow trench isolation in the high voltage region, with a step in trench depth between the high voltage region and the low voltage region.

The step may be generated as an etching rate in the HV region with its bonding force weakened by the ions with which the HV region of the semiconductor substrate is doped becomes larger than an etching rate in the LV region.

Embodiments relate to method of forming a STI for a semiconductor device, including: forming a pad oxide film pattern over a semiconductor substrate having a low voltage region and a high voltage region, forming a pad nitride film pattern over the pad oxide film pattern, forming a photoresist pattern for blocking the low voltage region, doping the high voltage region with ions by carrying out an ion implantation process using the PR pattern as a mask; and forming a shallow trench isolation in the low voltage region and a shallow trench isolation in the high voltage region, with a step in trench depth between the high and low voltage regions generated by the ions.

The ion implantation process may use boron as dopants if the semiconductor substrate is of P-type, and may use phosphorus or arsenic as dopants if the semiconductor substrate is of N-type. In the ion implantation process, ion process energy may be in a range of several Kev to several thousands Kev and a dose may be in a range of 10¹⁰ to 10¹⁶. The step may be generated as an etching rate in the HV region with its bonding force weakened by the ions with which the HV region of the semiconductor substrate is doped becomes larger than an etching rate in the LV region.

Embodiments relate to An apparatus configured to form a pad oxide film pattern over a semiconductor substrate having a low voltage region and a high voltage region, form a pad nitride film pattern over the pad oxide film pattern, form a photoresist pattern for blocking the low voltage region, dope the high voltage region with ions by carrying out an ion implantation process using the PR pattern as a mask, and form a shallow trench isolation in the low voltage region and a shallow trench isolation in the high voltage region, with a step in trench depth between the high and low voltage regions generated by the ions.

According to embodiments, by forming a dual STI in which a step is generated between a LV region and a HV region using an etching rate difference caused by ion doping in an etching process, an etching rate in the HV region becomes larger than an etching rate in the LV region so that no junction leakage occurs even for high current and voltage applied to the HV region, which results in reduction of BV (Breakthrough Voltage) fail and hence increase of semiconductor yield.

### DRAWINGS

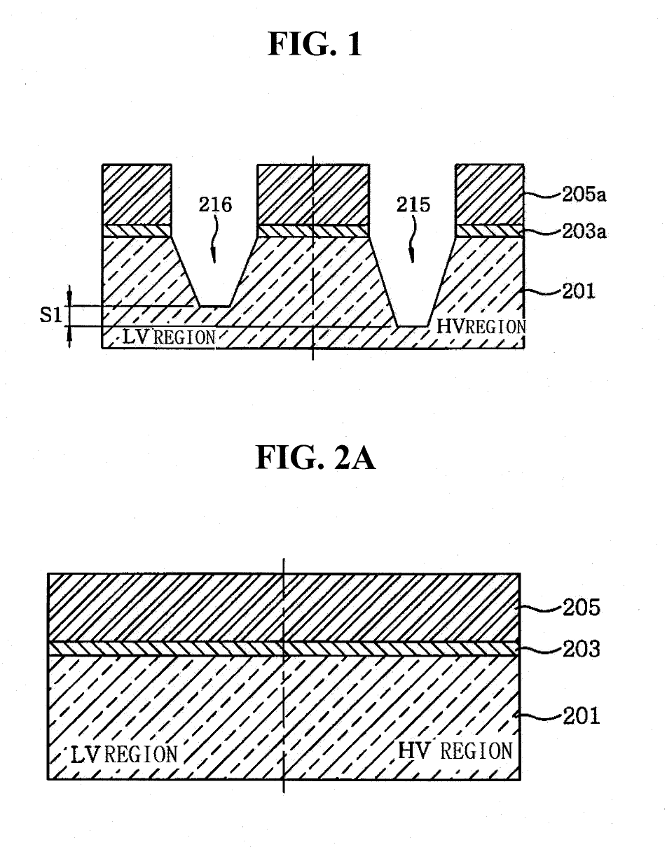

Example FIG. 1 is a sectional view showing a semiconductor device with a STI structure formed therein according to embodiments.

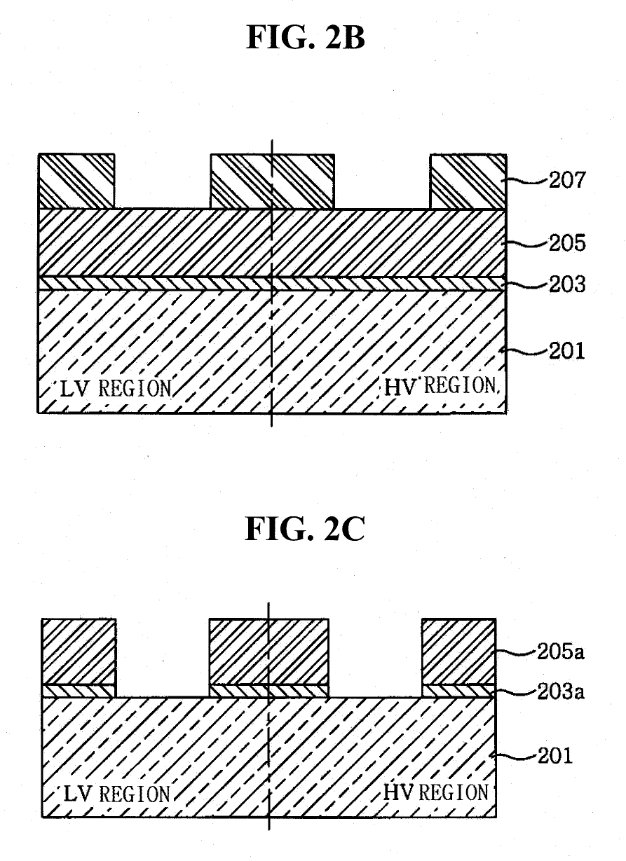

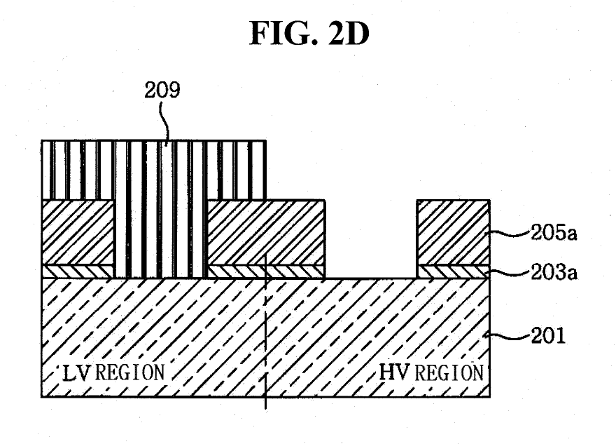

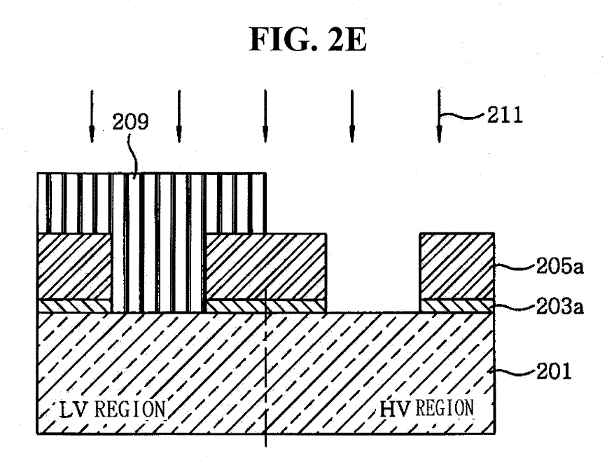

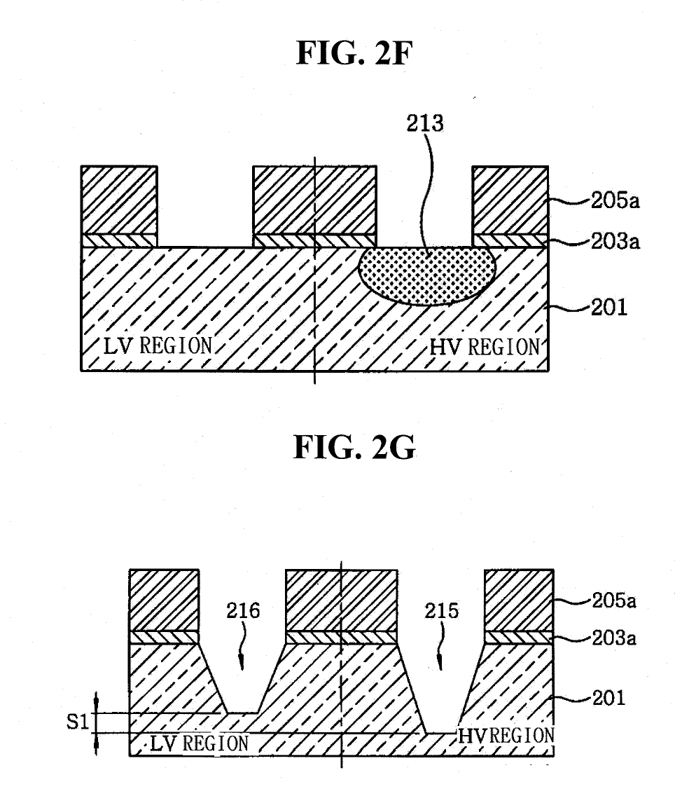

Example FIGS. 2A to 2G are vertical sectional views showing various steps of a method of forming an STI structure in a semiconductor device according to embodiments.

### DESCRIPTION

Example FIG. 1 is a sectional view showing a semiconductor device with a STI structure formed therein according to embodiments. Referring to example FIG. 1, a semiconductor device includes a semiconductor (for example, P type) substrate 201 having a LV region and a HV region. A pad oxide film pattern 203a and a pad nitride film pattern 205a are formed over the semiconductor substrate 201. An STI 216 formed in the LV region and an STI 215 in the HV region. A step S1 in trench depth is generated by ions with which the HV region on the semiconductor substrate 201 is doped when an etching process is carried out using the pad oxide film pattern 203a and pad nitride film pattern 205a as a mask.

Example FIGS. 2A to 2G are vertical sectional views showing various steps of a method of forming an STI structure in a semiconductor device according to embodiments. Referring to example FIG. 2A, first, a pad oxide film 203 and a pad nitride film 205 may be formed sequentially over the semiconductor substrate 2201 with an LV region and an HV region.

Next, by selectively removing some of a photoresist (PR) film formed over the entire surface of the pad nitride film 205 through an exposure and development process using a reticle designed to have a desired pattern, a PR pattern 207 may be formed to define STI regions, for example, as shown in example FIG. 2B. By selectively etching away some of the pad oxide film 203 and pad nitride film 205 using the PR pattern 207, so that some of the semiconductor substrate 201 can be exposed, the pad oxide film pattern 203a and the pad nitride film pattern 205a may be formed, for example, as shown in example FIG. 2C.

By selectively removing some of a PR film formed over the entire surface through an exposure and development process using a reticle designed to have a desired pattern, a PR pattern 209 may be formed to block the LV region, for example, as shown in example FIG. 2D.

Subsequently, an ion implantation process 211 may be carried out using the PR pattern 209 as a mask, for example, as shown in example FIG. 2E. As a result, the blocked LV region on the semiconductor substrate 201 is not doped with ions, while the non-blocked HV region may be doped with ions 213, for example, as shown in example FIG. 2F. The ion implantation process 211 may use boron as dopants if the semiconductor substrate 201 is of P-type, and may use phosphorus or arsenic as dopants if the semiconductor substrate 201 is of N-type. To obtain a large step depth between the LV region and the HV region, ion process energy or a dose has to be increased. To obtain a small step depth between the LV region and the HV region, ion process energy or a dose has to be decreased. For example, the ion process energy may be in a range of several KeV to several thousands of KeV and the dose may be in a range of 10¹⁰ to 10¹⁶.

Finally, after removing the PR pattern 209 remaining in the LV region using a streaming process, an etching process may be carried out using the pad oxide pattern 203a and pad nitride pattern 205a as a mask. As a result, the LV region STI 216 and the HV region STI 215 may be formed with the step S1 generated therebetween by the doping ions 213, for example, as shown in example FIG. 2G. Here, the step S1 may be generated as an etching rate in the HV region with its bonding force weakened by the ions 213 with which the HV region of the semiconductor substrate 201 is doped becomes larger than an etching rate in the LV region.

As described above, according to embodiments, by forming a dual STI in which a step is generated between a LV region and a HV region using an etching rate difference caused by ion doping in an etching process, an etching rate in the HV region becomes larger than an etching rate in the LV region. No junction leakage occurs even for high current and voltage applied to the HV region, which results in reduction of BV fail.

It will be obvious and apparent to those skilled in the art that various modifications and variations can be made in the embodiments disclosed. Thus, it is intended that the disclosed embodiments cover the obvious and apparent modifications and variations, provided that they are within the scope of the appended claims and their equivalents.

What is claimed is:

1. An apparatus comprising:
a semiconductor substrate having a low voltage region and a high voltage region;
a pad oxide film pattern formed over the semiconductor substrate;
a pad nitride film pattern formed over the pad oxide film; and
a shallow trench isolation formed in the low voltage region and a shallow trench isolation in the high voltage region, with a step in trench depth between the high voltage region and the low voltage region.

2. The apparatus of claim 1, wherein the trench depth is deeper in the high voltage region than in the low voltage region.

3. The apparatus of claim 1, wherein the step in trench depth is generated by ions with which the high voltage region on the semiconductor substrate is doped when an etching process is carried out using the pad oxide film pattern and pad nitride film pattern as a mask.

4. The apparatus of claim 3, wherein the high voltage region has a bonding force weakened by dopant ions.

5. A method comprising:
forming a pad oxide film pattern over a semiconductor substrate having a low voltage region and a high voltage region;
forming a pad nitride film pattern over the pad oxide film pattern;
forming a photoresist pattern for blocking the low voltage region;
doping the high voltage region with ions by carrying out an ion implantation process using the PR pattern as a mask; and
forming a shallow trench isolation in the low voltage region and a shallow trench isolation in the high voltage region, with a step in trench depth between the high and low voltage regions generated by the ions.

6. The method of claim 5, wherein the step is generated by the ions by carrying out an etching process.

7. The method of claim 6, wherein the etching process uses the pad oxide film pattern and pad nitride film pattern as a mask.

8. The method of claim 5, wherein the ion implantation process uses boron as dopant if the semiconductor substrate is of P-type.

9. The method of claim 5, wherein the ion implantation process uses one of phosphorus and arsenic as dopant if the semiconductor substrate is of N-type.

10. The method of claim 5, wherein, in the ion implantation process, ion process energy is in a range of several KeV to several thousands KeV.

11. The method of claim 5, wherein, in the ion implantation process, a dose is in a range of 10¹⁰ to 10¹⁶.

12. The method of claim 7, wherein the step is generated as an etching rate in the high voltage region with its bonding force weakened by the ions with which the high voltage region of the semiconductor substrate is doped becomes larger than an etching rate in the low voltage region.

13. An apparatus configured to:
form a pad oxide film pattern over a semiconductor substrate having a low voltage region and a high voltage region;
form a pad nitride film pattern over the pad oxide film pattern;
form a photoresist pattern for blocking the low voltage region;
dope the high voltage region with ions by carrying out an ion implantation process using the PR pattern as a mask; and
form a shallow trench isolation in the low voltage region and a shallow trench isolation in the high voltage region, with a step in trench depth between the high and low voltage regions generated by the ions.

14. The apparatus of claim 13, wherein the step is generated by the ions by carrying out an etching process.

15. The apparatus of claim 14, wherein the etching process uses the pad oxide film pattern and pad nitride film pattern as a mask.

16. The apparatus of claim 15, wherein the step is generated as an etching rate in the high voltage region with its bonding force weakened by the ions with which the high voltage region of the semiconductor substrate is doped becomes larger than an etching rate in the low voltage region.

17. The apparatus of claim 13, wherein the ion implantation process uses boron as dopant if the semiconductor substrate is of P-type.

18. The apparatus of claim 13, wherein the ion implantation process uses one of phosphorus and arsenic as dopant if the semiconductor substrate is of N-type.

19. The apparatus of claim 13, wherein, in the ion implantation process, ion process energy is in a range of several KeV to several thousands KeV.

20. The apparatus of claim 13, wherein, in the ion implantation process, a dose is in a range of 10¹⁰ to 10¹⁶.
